(19) United States
(12) Patent Application Publication
(10) Pub. No.: US 2016/0048424 A1
(43) Pub. Date: Feb. 18, 2016

(54) SEMICONDUCTOR MEMORY DEVICE

(71) Applicants: Shintaro SAKAI, Seoul (KR); Hiromi NORO, Seoul (KR)

(72) Inventors: Shintaro SAKAI, Seoul (KR); Hiromi NORO, Seoul (KR)

(21) Appl. No.: 14/644,132

(22) Filed: Mar. 10, 2015

Related U.S. Application Data
(60) Provisional application No. 62/036,781, filed on Aug. 13, 2014.

(51) Int. Cl. G06F 11/10; G11C 11/16

(52) U.S. Cl. CPC G06F 11/1008; G11C 11/1675; G11C 11/1673

(57) ABSTRACT

According to one embodiment, a semiconductor memory device includes first and second banks, each of the first and second banks comprising a memory cell array; a data buffer a data buffer which is shared by the first and second banks, and stores write data which is to be written to the first and second banks and read data which is read from the first and second banks; a correcting circuit which is shared by the first and second banks, and corrects an error of the read data; and a multiplexer which switches a connection between the first bank and the data buffer and correcting circuit, and switches a connection between the second bank and the data buffer and correcting circuit. The multiplexer is disposed between the data buffer and the correcting circuit.

### CROSS-REFERENCE TO RELATED APPLICATIONS

This application claims the benefit of U.S. Provisional Application No. 62/036,781, filed Aug. 13, 2014, the entire contents of which are incorporated herein by reference.

### FIELD

Embodiments described herein relate generally to a semiconductor memory device.

### BACKGROUND

A resistance change type memory is known as a kind of semiconductor memory device. In addition, a magnetoresistive random access memory (MRAM) is known as a kind of resistance change type memory. The MRAM is a memory device using a magnetic element having a magnetoresistive effect for a memory cell which stores information. Attention has been paid to the MRAM as a next-generation memory device which is characterized by a high speed operation, a large capacity and nonvolatility. Furthermore, the MRAM has been researched and developed as a substitute for a volatile memory such as a DRAM or an SRAM.

### BRIEF DESCRIPTION OF THE DRAWINGS

FIG. 1 is a block diagram of a semiconductor memory device according to an embodiment;

FIG. 2 is a block diagram of two half-banks shown in FIG. 1;

FIG. 3 is a circuit diagram of a memory cell array included in a quarter-bank;

FIG. 4 is a cross-sectional view of an MTJ element;

FIG. 5 is a block diagram of a column control circuit according to a first example;

FIG. 6 is a block diagram of a column control circuit according to a second example;

FIG. 7 is a block diagram of an ECC circuit according to a first example; and

FIG. 8 is a block diagram of an ECC circuit according to a second example.

### DETAILED DESCRIPTION

In general, according to one embodiment, there is provided a semiconductor memory device comprising:

first and second banks, each of the first and second banks comprising a memory cell array;

a data buffer a data buffer which is shared by the first and second banks, and stores write data which is to be written to the first and second banks and read data which is read from the first and second banks;

a correcting circuit which is shared by the first and second banks, and corrects an error of the read data; and

a multiplexer which switches a connection between the first bank and the data buffer and correcting circuit, and switches a connection between the second bank and the data buffer and correcting circuit,

wherein the multiplexer is disposed between the data buffer and the correcting circuit.

Embodiments will be described hereinafter with reference to the accompanying drawings. In the description below, structural elements having substantially identical functions and structures are denoted by like reference numerals, and an overlapping description will be given only where necessary. The drawings are schematic ones. Each embodiment illustrates a device or a method for embodying the technical concept of the embodiment, and the technical concept of the embodiment does not restrict the materials, shapes, structures, dispositions, etc. of the structural elements to those described below.

In the embodiment below, a magnetoresistive random access memory (MRAM), which is a kind of resistance change type memory, is described as the semiconductor memory device by way of example.

[1] Structure of Semiconductor Memory Device

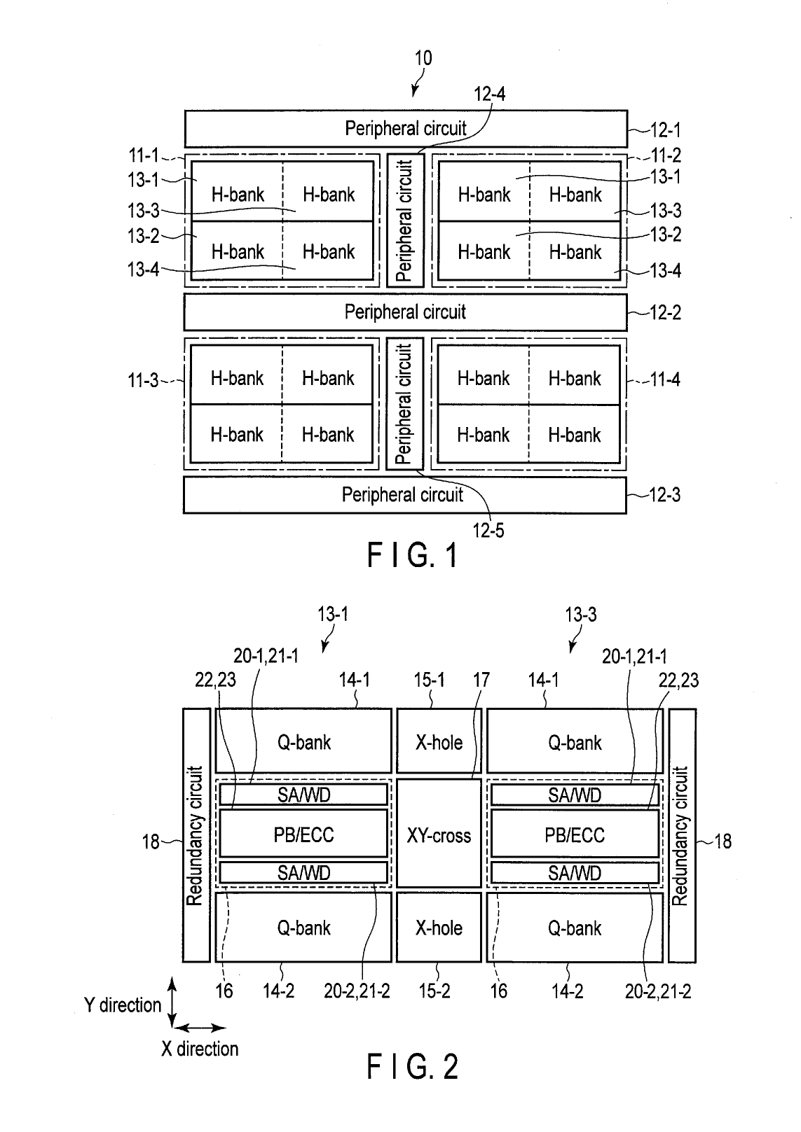

FIG. 1 is a block diagram of a semiconductor memory device 10 according to the embodiment. The semiconductor memory device (MRAM) 10 comprises a plurality of memory core circuits 11, and peripheral circuits 12 (12-1 to 12-5) provided around the plural memory core circuits 11. In FIG. 1, four memory core circuits 11-1 to 11-4 are illustrated by way of example. Incidentally, in the description of the present embodiment, when there is no need to distinguish the plural memory core circuits 11-1 to 11-4, the memory core circuit is described with the reference numeral without the suffix number, and the description of this memory circuit corresponds to the description of each of the plural memory core circuits 11-1 to 11-4. As regards the other reference numerals with suffix numbers, the same as in the case of memory core circuits 11 applies.

The memory core circuit 11 comprises, for example, four half-banks (H-bank) 13-1 to 13-4. For example, a first bank is composed of a half-bank 13-1 included in the memory core circuit 11-1, and a half-bank 13-1 included in the memory core circuit 11-2. Similarly, a second bank to a fourth bank are composed of half-banks 13-2 to 13-4 included in the memory core circuit 11-1, and half-banks 13-2 to 13-4 included in the memory core circuit 11-2, respectively. Incidentally, the definitions and assignments of the banks can arbitrarily be set.

The peripheral circuit 12 comprises a pad, an input/output circuit, an address buffer, a command buffer, a test mode circuit, a control circuit which controls these components, and others. For example, the peripheral circuit 12-1 comprises an address/command pad (CA pad), an address buffer, a command buffer, a test mode circuit, and a control circuit. The peripheral circuit 12-3 comprises a data input/output pad (DQ pad), an input/output circuit, and others. The peripheral circuits 12-4, 12-5 comprise interconnections for electrically connecting the peripheral circuit 12-1 and the peripheral circuit 12-3.

FIG. 2 is a block diagram of the two half-banks 13-1, 13-3 shown in FIG. 1. The two half-banks 13-1, 13-3 neighbor in an X direction (row direction).

The half-bank 13-1 includes two quarter-banks (Q-bank) 14-1, 14-2, two row control circuits (X-hole) 15-1, 15-2, a column control circuit 16, a row/column control circuit 17, and a redundancy circuit 18. The quarter-banks 14-1, 14-2 are disposed in a manner to sandwich the column control circuit 16. The half-bank 13-3 has the same structure as the half-bank 13-1. The row control circuits 15-1, 15-2 and the row/column control circuit 17 are shared by the half-banks 13-1, 13-3.

The quarter-bank 14 comprises a memory cell array in which a plurality of memory cells are arranged in a matrix. The memory cell comprises a magnetoresistive effect element. In addition, the quarter-bank 14 comprises a column switch circuit for selecting a column of the memory cell array, and others.

The row control circuit 15 is connected to word lines which are provided in the memory cell array, and executes control of rows. The row control circuit 15 includes a WL driver for driving word lines, and others.

The column control circuit 16 is connected to bit lines which are provided in the memory cell array, and executes control of columns. The column control circuit 16 comprises sense amplifiers (SA) 20-1, 20-2, write drivers (WD) 21-1, 21-2, a page buffer 22, and an error checking and correcting (ECC) circuit 23. The sense amplifier 20-1 and write driver 21-1 are used for the quarter-bank 14-1, and the sense amplifier 20-2 and write driver 21-2 are used for the quarter-bank 14-2. The page buffer 22 and ECC circuit 23 are shared by the quarter-banks 14-1, 14-2.

The sense amplifier (read circuit) 20 senses and amplifies read data which is read from the memory cell array to the bit lines. The write driver (write circuit) 21 writes write data, which is sent from the input/output circuit, to the memory cell array via the bit lines.

The page buffer (data buffer) 22 temporarily stores write data, which is sent from the input/output circuit, at a time of data write, and temporarily stores read data, which is sent from the quarter-bank, at a time of data read.

The ECC circuit 23 generates an error correction code by using write data at a time of data write. The error correction code is written to the memory cell array together with the write data. In addition, the ECC circuit 23 corrects an error of read data at a time of data read, by using the error correction code included in the read data. The error correction code is excluded from the read data. To be more specific, in response to an active command, a corresponding row is activated. A page, which has been read from the activated row, is stored in the page buffer 22. The ECC circuit 23 executes error correction by using the page stored in the page buffer 22.

The row/column control circuit 17 comprises a row decoder which decodes a row address, and a column decoder which decodes a column address. The redundancy circuit 18 is a circuit for relieving a defective memory cell, and includes a redundancy fuse which stores an address for replacing the defective memory cell with a normal memory cell.

[1-1] Structure of Memory Cell Array

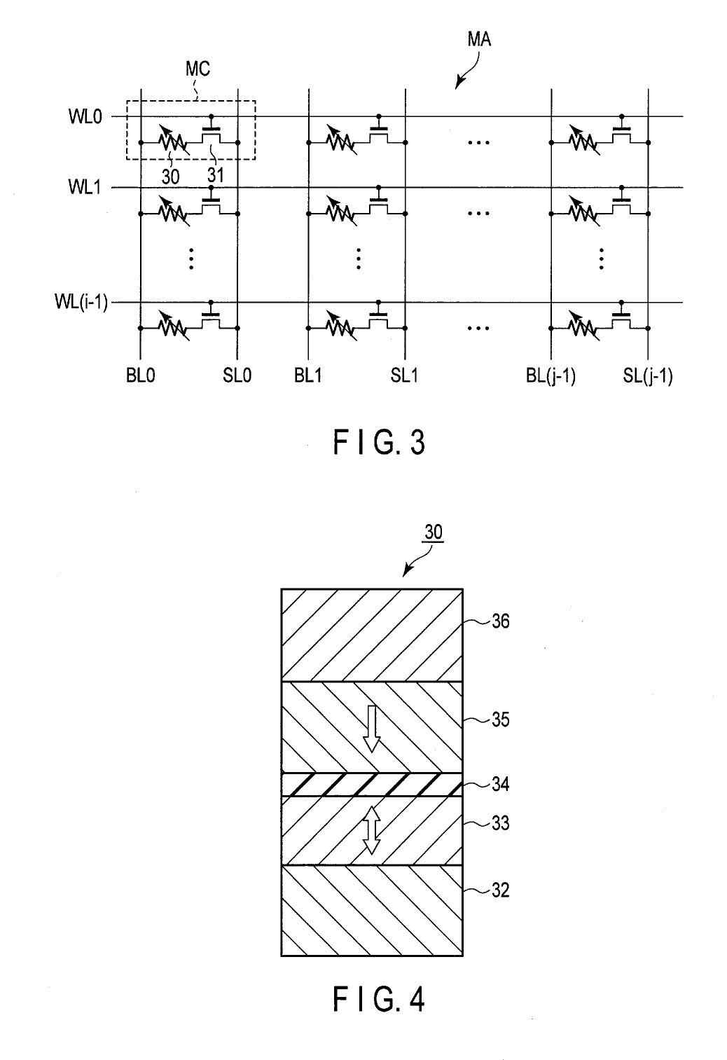

Next, a description is given of an example of the structure of a memory cell array MA included in the quarter-bank 14. FIG. 3 is a circuit diagram of the memory cell array MA included in the quarter-bank 14.

The memory cell array MA is constructed such that a plurality of memory cells MC are arranged in a matrix. In the memory cell array MA, a plurality (i) of word lines WLO to WL(i−1), a plurality (j) of bit lines BLO to BL(j−1), and a plurality (j) of source lines SLO to SL(j−1) are provided. A row of the memory cell array MA is connected to one word line WL, and a column of the memory cell array MA is connected to a pair which is composed of one bit line BL and one source line SL.

The memory cell MC is composed of a magnetoresistive effect element (magnetic tunnel junction (MTJ) element) 30 and a select transistor 31. The select transistor 31 is composed of, for example, an N-channel MOSFET.

One end of the MTJ element 30 is connected to the bit line BL, and the other end of the MTJ element 30 is connected to the drain of the select transistor 31. The gate of the select transistor 31 is connected to the word line WL, and the source of the select transistor 31 is connected to the source line SL.

[1-2] Structure of MTJ Element

Next, an example of the structure of the MTJ element 30 is described. FIG. 4 is a cross-sectional view of the MTJ element 30. The MTJ element 30 is constructed such that a lower electrode 32, a memory layer (free layer) 33, a nonmagnetic layer (tunnel barrier layer) 34, a reference layer (fixed layer) 35 and an upper electrode 36 are stacked in order. The order of stacking of the memory layer 33 and the reference layer 35 may be reversed.

Each of the memory layer 33 and reference layer 35 is formed of a ferromagnetic material. An insulative material, such as MgO, is used for the tunnel barrier layer 34.

Each of the memory layer 33 and reference layer 35 has, for example, a magnetic anisotropy in a vertical direction, and the direction of easy magnetization of the memory layer 33 and reference layer 35 is the vertical direction. Incidentally, the magnetization direction of the memory layer 33 and reference layer 35 may be an in-plane direction.

The magnetization direction of the memory layer 33 is variable (reversible). The magnetization direction of the reference layer 35 is invariable (fixed). The reference layer 35 is set to have a sufficiently greater vertical magnetic anisotropy energy than the memory layer 33. The setting of the magnetic anisotropy is enabled by adjusting the material composition or the film thickness. In this manner, the magnetization reversal current of the memory layer 33 is set to be small, and the magnetization reversal current of the reference layer 35 is set to be larger than that of the memory layer 33. Thereby, the MTJ element 30 is realized, which comprises the memory layer 33 with the magnetization direction that can be varied by a predetermined write current, and the reference layer 35 with the magnetization direction that cannot be varied by the predetermined write current.

In the present embodiment, use is made of a spin-transfer writing method in which a write current is caused to directly flow in the MTJ element 30, and the state of magnetization of the MTJ element 30 is controlled by this write current. The MTJ element 30 can take either a low resistance state or a high resistance state, depending on whether the relative relationship of magnetization between the memory layer 33 and reference layer 35 is parallel or antiparallel.

If a write current in a direction from the memory layer 33 toward the reference layer 35 is caused to flow in the MTJ element 30, the relative relationship of magnetization between the memory layer 33 and reference layer 35 becomes parallel. In the case of this parallel state, the resistance value of the MTJ element 30 becomes lowest, and the MTJ element 30 is set in the low resistance state. The low resistance state of the MTJ element 30 is defined, for example, as data “0”.

On the other hand, if a write current in a direction from the reference layer 35 toward the memory layer 33 is caused to flow in the MTJ element 30, the relative relationship of magnetization between the memory layer 33 and reference layer 35 becomes antiparallel. In the case of this antiparallel state, the resistance value of the MTJ element 30 becomes highest, and the MTJ element 30 is set in the high resistance state. The high resistance state of the MTJ element 30 is defined, for example, as data “1”.

Thereby, the MTJ element 30 can be used as a memory element which can store 1-bit data (2-value data). The assignment between the resistance state and data of the MTJ element 30 can arbitrarily be set.

When data is read from the MTJ element 30, a read voltage is applied to the MTJ element 30, and a resistance value of the MTJ element 30 is detected based on the read current flowing in the MTJ element 30 at this time. This read voltage is set at a sufficiently lower value that the threshold of magnetization reversal by spin transfer.

[2] Structure of Column Control Circuit 16

Next, the detailed structure of the column control circuit 16 is described.

### [2-1] First Example

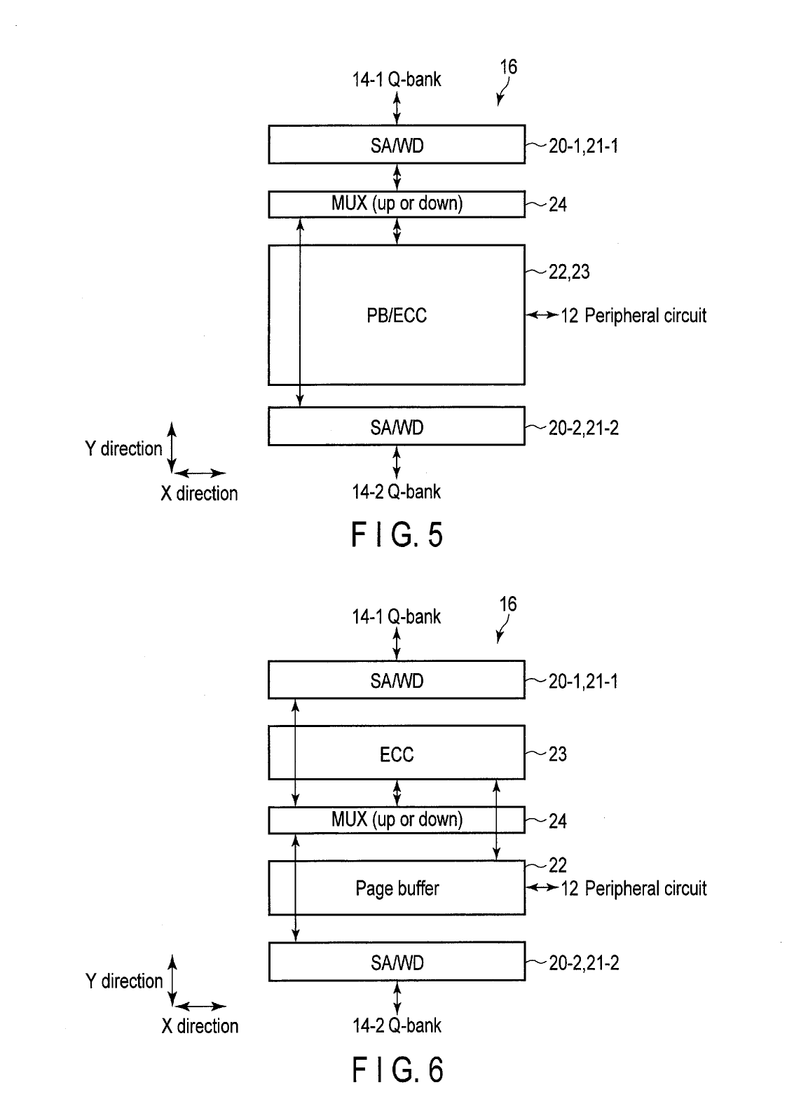

To begin with, a first example of the column control circuit 16 is described. FIG. 5 is a block diagram of the column control circuit according to the first example.

The page buffer 22 and ECC circuit 23 are shared by the upper and lower quarter-banks 14-1, 14-2. A multiplexer (MUX) 24 connects either the upper-side sense amplifier 20-1/write driver 21-1 or the lower-side sense amplifier 20-2/write driver 21-2 to the page buffer 22/ECC circuit 23. The selection operation of the multiplexer 24 is controlled by a select signal which is sent from the peripheral circuit 12.

According to the first example, it should suffice if one page buffer and one ECC circuit are disposed for the two quarter-banks. Thereby, the area of the column control circuit 16 can be reduced.

However, in the structure example of FIG. 5, the distance between the multiplexer 24 and the sense amplifier 20-2/write driver 21-2 is longer than the distance between the multiplexer 24 and the sense amplifier 20-1/write driver 21-1. Since this difference in distance corresponds to the difference in length of signal lines, a signal delay occurs on the side of the longer signal line. In order to adjust this signal delay, a timing control circuit is needed. Furthermore, since rate-determination is made by the quarter-bank with a larger signal delay, the operation speed of the semiconductor memory device 10 deteriorates.

### [2-2] Second Example

Next, a second example of the column control circuit 16 is described. FIG. 6 is a block diagram of the column control circuit 16 according to the second example.

The page buffer 22 and ECC circuit 23 are shared by the upper and lower quarter-banks 14-1, 14-2. The function of the multiplexer 24 is the same as in the first example. In this example, the multiplexer 24 is disposed between the page buffer 22 and ECC circuit 23. Specifically, the page buffer 22, multiplexer 24 and ECC circuit 23 are disposed in the named order in the Y direction. The flow of data at a time of write is in the order of the page buffer, ECC circuit, multiplexer and write driver. In addition, the flow of data at a time of read is in the order of the sense amplifier, multiplexer, ECC circuit and page buffer.

In the structure example of FIG. 6, the difference between the distance between the multiplexer 24 and the sense amplifier 20-2/write driver 21-2, on the one hand, and the distance between the multiplexer 24 and the sense amplifier 20-1/write driver 21-1, on the other hand, is less than in the first example. Thereby, the difference in signal delay between the two quarter-banks can be reduced. Thus, the timing control can easily be executed and, for example, a timing control circuit relating to a signal delay becomes needless. Furthermore, it is possible to suppress deterioration of the operation speed of the semiconductor memory device 10.

[3] Structure of ECC Circuit

Next, detailed structure examples of the ECC circuit 23 are described. In general, the area of the ECC circuit 23 is greater than the area of the page buffer 22. Thus, in order to further reduce the difference in signal delay, it is desirable to reduce the area of the ECC circuit 23, specifically, the length of the ECC circuit 23 in the Y direction.

### [3-1] First Example

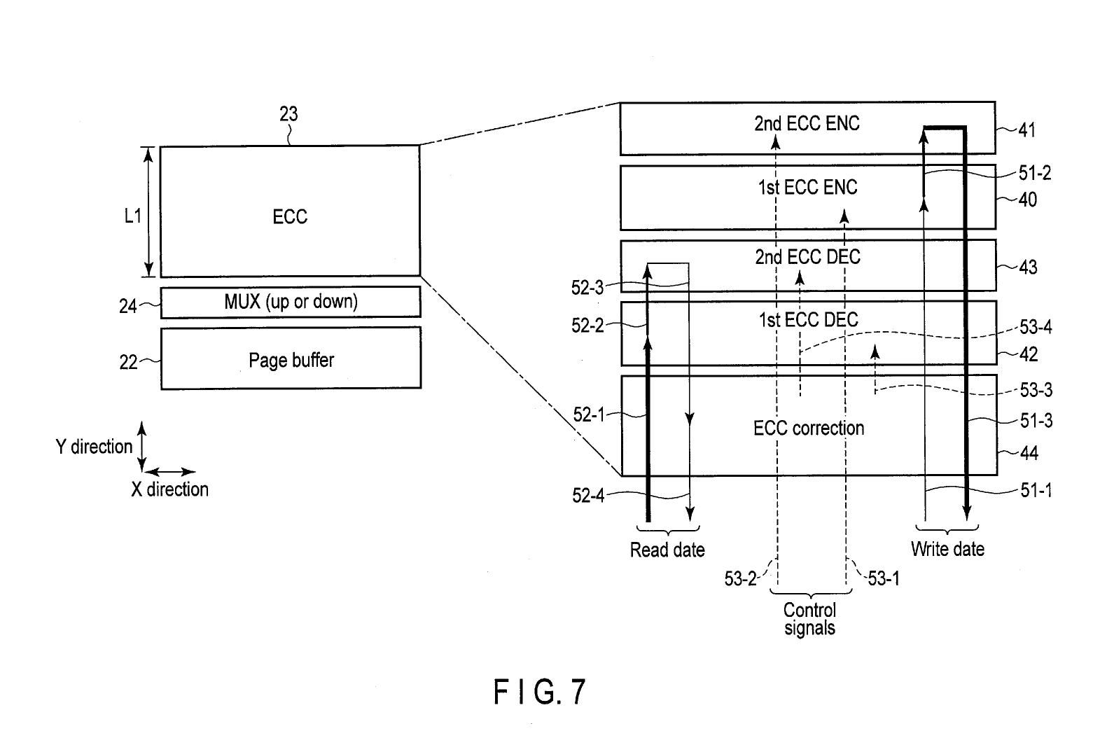

To begin with, a first example of the ECC circuit 23 is described. FIG. 7 is a block diagram of an ECC circuit 23 according to the first example. Solid-line arrows in FIG. 7 schematically indicate data lines (data buses) and flows of data, and broken-line arrows in FIG. 7 schematically indicate control signal lines and flows of signal lines.

The ECC circuit 23 comprises a first ECC encoder 40, a second ECC encoder 41, a first ECC decoder 42, a second ECC decoder 43, and an error correction circuit 44. The first ECC encoder 40 and second ECC encoder 41 generate an error correction code (e.g. a parity code) by using write data. In addition, the first ECC encoder 40 and second ECC encoder 41 perform an encode operation in two stages. The flow of data is in the order of the first ECC encoder 40 and second ECC encoder 41.

Write data is input to the first ECC encoder 40 via a data bus 51-1. The first ECC encoder 40 is connected to the second ECC encoder 41 via data bus 51-2. The write data is output from the second ECC encoder 41 to a data bus 51-3. A control signal is input to the first ECC encoder 40 via a signal line 53-1. A control signal is input to the second ECC encoder 41 via a signal line 53-2.

The first ECC decoder 42 generates an error correction code by using read data. The second ECC decoder 43 compares an error correction code which has been read from the memory cell array, and the error correction code, which has been generated by the first ECC decoder 42, thereby executing error detection, that is, determining whether there is an error in the read data. When an error has been detected by the second ECC decoder 43, the correction circuit 44 executes error correction, that is, corrects a defective bit by using the error correction code.

Read data is input to the first ECC decoder 42 via a data bus 52-1. The first ECC decoder 42 is connected to the second ECC decoder 43 via a data bus 52-2. The second ECC decoder 43 is connected to the correction circuit 44 via a data bus 52-3. The read data is output to a data bus 52-4 from the correction circuit 44. A control signal is input to the first ECC decoder 42 via a signal line 53-3. A control signal is input to the second ECC decoder 43 via a signal line 53-4.

In the structure example of FIG. 7, the plural circuit components, which constitute the ECC circuit 23, are disposed in the Y direction. Thus, a length L1 in the Y direction of the ECC circuit 23 is large. Specifically, the size of the ECC circuit 23 is larger than that of the page buffer 22.

In addition, in the area of the first ECC decoder 42, although there is an allowance for the space for arranging circuits, interconnections are provided most densely, and it is thus difficult to secure a sufficient inter-line space. Consequently, an area for securing an interconnection region is necessary, and as a result the size of the ECC circuit 23 becomes larger and, in particular, the length in the X direction becomes larger.

### [3-2] Second Example

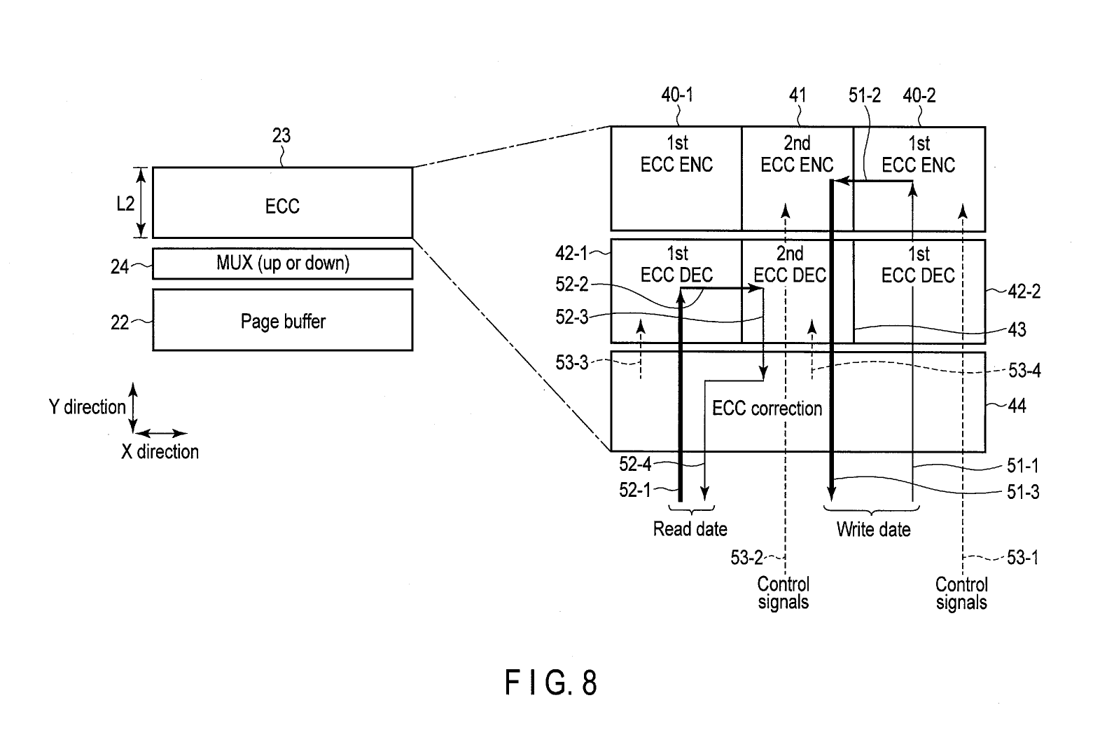

Next, a second example of the ECC circuit 23 is described. FIG. 8 is a block diagram of an ECC circuit 23 according to the second example. Solid-line arrows and broken-line arrows in FIG. 8 correspond to the solid-line arrows and broken-line arrows in FIG. 7.

The first ECC encoder 40 is divided into two first ECC encoders (encoding portions) 40-1, 40-2. The functions of the two first ECC encoders 40-1, 40-2 are the same as the function of the first ECC encoder 40 of the first example. In addition, the first ECC decoder 42 is divided into two first ECC decoders (decoding portions) 42-1, 42-2. The functions of the two first ECC decoders 42-1, 42-2 are the same as the function of the first ECC decoder 42 of the first example.

The first ECC encoder 40-1, second ECC encoder 41 and first ECC encoder 40-2 are disposed in the named order in the X direction. The first ECC decoder 42-1, second ECC decoder 43 and first ECC decoder 42-2 are disposed in the named order in the X direction.

In the first example, as illustrated in FIG. 7, the ECC circuit 23 is composed of the five-row circuit components arranged in the Y direction. By contrast, in the second example, as illustrated in FIG. 8, the ECC circuit 23 is composed of the three-row circuit components arranged in the Y direction. Thus, in the second example, a length L2 in the Y direction of the ECC circuit 23 is shorter than the length L1 of the first example. Specifically, the length in the Y direction of the ECC circuit 23 can be made closer to the length in the Y direction of the page buffer 22.

[4] Advantageous Effects

As has been described above in detail, in the present embodiment, the page buffer 22 and ECC circuit 23 are shared by the two quarter-banks 14-1, 14-2. In addition, the multiplexer 24 switches the connection between the quarter-bank 14-1, 14-2 and the page buffer 22 and ECC circuit 23. In addition, the multiplexer 24 is disposed between the page buffer 22 and ECC circuit 23, which are arranged in the Y direction.

Therefore, according to the present embodiment, the difference between the distance between the multiplexer 24 and quarter-bank 14-1, on the one hand, and the distance between the multiplexer 24 and quarter-bank 14-2, on the other hand, can be reduced. Thereby, the difference in signal delay between the two quarter-banks can be reduced. As a result, the timing control can easily be executed, and the degradation in operation speed of the semiconductor memory device 10 can be suppressed.

In addition, in the embodiment, the first ECC encoder 40 and second ECC encoder 41 are disposed along the X direction, and the first ECC decoder 42 and second ECC decoder 43 are disposed along the X direction. Thereby, the length in the Y direction of the ECC circuit 23 can be made closer to the length in the Y direction of the page buffer 22. Thereby, the difference in signal delay can further be reduced.

Besides, the number of interconnections extending above the first ECC decoder 41 can be reduced. Thereby, since the inter-line space can be secured, the inter-line capacitance can be reduced and the degradation in operation speed can be suppressed. Furthermore, since the circuit size of the ECC circuit 23 can be specified without being restricted by the number of interconnections, the circuit area of the ECC circuit 23 can be reduced.

In the meantime, the MRAM illustrated in each of the above-described embodiments may be a spin-transfer torque magnetoresistive random access memory (STT-MRAM) which makes use of a spin-transfer phenomenon in the magnetization reversal of the magnetic layer.

Besides, in each of the above-described embodiments, the MRAM using the magnetoresistive effect element has been described as the semiconductor device by way of example, but the embodiments are not limited to this, and are applicable to various kinds of semiconductor memory devices, regardless of volatile memories and nonvolatile memories. In addition, the embodiments are applicable to resistance change type memories similar to the MRAM, such as a resistive random access memory (ReRAM) and a phase-change random access memory (PCRAM).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
first and second banks, each of the first and second banks comprising a memory cell array;
a data buffer which is shared by the first and second banks, and stores write data which is to be written to the first and second banks and read data which is read from the first and second banks;
a correcting circuit which is shared by the first and second banks, and corrects an error of the read data; and
a multiplexer which switches a connection between the first bank and the data buffer and correcting circuit, and switches a connection between the second bank and the data buffer and correcting circuit,
wherein the multiplexer is disposed between the data buffer and the correcting circuit.

2. The device of claim 1, wherein the first and second banks sandwich the data buffer, the correcting circuit and the multiplexer.

3. The device of claim 1, further comprising:
a first sense amplifier which reads data from the first bank; and
a second sense amplifier which reads data from the second bank,
wherein the first sense amplifier is disposed between the first bank and the multiplexer, and
the second sense amplifier is disposed between the second bank and the multiplexer.

4. The device of claim 1, further comprising:
a first write driver which writes data to the first bank; and
a second write driver which writes data to the second bank,
wherein the first write driver is disposed between the first bank and the multiplexer, and
the second write driver is disposed between the second bank and the multiplexer.

5. The device of claim 1, wherein the correcting circuit comprises:
first and second encoders which generate an error correction code for the write data; and
first and second decoders which detect an error of the read data by using the error correction code.

6. The device of claim 5, wherein
the first and second encoders are arranged in a second direction which crosses a first direction from the data buffer toward the correcting circuit, and
the first and second decoders are arranged in the second direction.

7. The device of claim 6, wherein
the first encoder comprises first and second encoding portions, and
the second encoder is disposed between the first and second encoding portions.

8. The device of claim 6, wherein
the first decoder comprises first and second decoding portions, and
the second decoder is disposed between the first and second decoding portions.

9. The device of claim 1, wherein the memory cell array comprises a magnetoresistive effect element.

10. The device of claim 1, wherein the semiconductor memory device is a spin-transfer torque magnetoresistive random access memory (STT-MRAM).
